(19) United States
(12) Patent Application Publication
(10) Pub. No.: US 2005/0285122 A1
(43) Pub. Date: Dec. 29, 2005

(54) Light emitting display and fabrication method thereof

(76) Inventor: Woong-Sik Choi, Wonjong-dong (KR)

Correspondence Address: Robert E. Bushnell, Suite 300, 1522 K Street, N.W., Washington, DC, 20005, US

(21) Appl. No.: 11/141,198

(22) Filed: Jun. 1, 2005

(30) Foreign Application Priority Data
Jun. 25, 2004 (KR) 2004-48316

(51) Int. Cl. H01L 29/18; H01L 21/00

(52) U.S. Cl. 257/88; 257/432; 438/48

(57) ABSTRACT

In a light emitting display and a fabrication method thereof, a stripe pattern displayed due to characteristic differences of a driving transistor is prevented, thereby enhancing picture quality. The light emitting display comprises: a plurality of light emitting devices formed adjacent to a region where data and scan lines cross each other; and a plurality of pixel circuits, each including a driving transistor for supplying current corresponding to a data signal to a respective one of the light emitting devices. The positions of the driving transistors are different from each other with respect to at least one of horizontal and vertical directions. With this configuration, a stripe pattern is prevented from appearing perpendicular to a scanning direction of a line beam emitted from an excimer laser during the fabrication method.

### CLAIM OF PRIORITY

This application makes reference to, incorporates the same herein, and claims all benefits accruing under 35 U.S.C. §119 from an application for LIGHTEMITTING DISPLAY AND FABRICATION METHOD THEREOF earlier filed in the Korean Intellectual Property Office on Jun. 25, 2004 and there duly assigned Serial No. 2004-48316.

### BACKGROUND OF THE INVENTION

1. Technical Field

The present invention relates to a light emitting display and, more particularly, to a light emitting display and a fabrication method thereof, in which a stripe pattern displayed due to the characteristic difference of a driving transistor is prevented, thereby enhancing picture quality.

2. Related Art

Recently, various flat panel displays have been developed, which substitute for a cathode ray tube (CRT) display because the CRT display is relatively heavy and bulky. Flat panel displays include a liquid crystal display (LCD), a field emission display (FED), a plasma display panel (PDP), a light emitting display (LED), etc.

Among the flat panel displays, the light emitting display can emit light for itself by electron-hole recombination, allowing a fluorescent layer thereof to emit the light. Such a light emitting display has advantages in that response time is relatively fast and power consumption is relatively low. However, such a light emitting display also has disadvantages.

For example, such a light emitting display typically has pixel circuits which employ driving thin film transistors (TFTs) which have characteristics which are non-uniform in nature. Such non-uniform characteristics include threshold voltage, mobility, and the like.

In addition, light emitting displays are fabricated by utilization of a laser crystallization process which has certain advantages, but which is also burdened by a disadvantage in that energy deviation in a laser beam used in laser scanning operations causes variation in certain characteristics of a poly silicon formed as a result. Such variable characteristics include crystal grain size, mobility of the poly silicon layers, and the like.

Thus, there is a need for a light emitting display and a method of fabricating the same which overcome these disadvantages.

### SUMMARY OF THE INVENTION

Accordingly, it is an object of the present invention to provide a light emitting display and a fabrication method thereof, in which a stripe pattern due to non-uniform characteristics of a driving transistor is prevented, thereby providing uniform picture quality.

The forgoing and/or other objects of the present invention are achieved by providing a light emitting display comprising: a plurality of light emitting devices formed so as to be adjacent to a region where data and scan lines cross each other; and a plurality of pixel circuits, each including a driving transistor for supplying, to a respective one of the light emitting 3 devices, current corresponding to a data signal of the data line, wherein the positions of the 4 plurality of driving transistors are different from each other with respect to at least one of horizontal and vertical directions.

According to an aspect of the invention, the driving transistors connected to odd numbered data lines are aligned in a first horizontal line, and the driving transistors connected to even numbered data lines are aligned in a second horizontal line between the first horizontal line and one of the scan lines.

According to another aspect of the invention, the driving transistors are disposed in zigzag fashion on the first and second horizontal lines.

According to another aspect of the invention, the driving transistors connected to odd numbered scan lines are aligned in a first vertical line, and the driving transistors connected to even numbered scan lines are aligned in a second vertical line between the first vertical line and one of the data lines.

According to another aspect of the invention, the driving transistors are disposed in zigzag fashion on the first and second vertical lines.

According to another aspect of the invention, each pixel circuit comprises: a switching transistor supplying a data signal from the data line to a gate electrode of a respective one of the driving transistors in response to a selection signal of the scan signal; and a storage capacitor connected between the gate electrode of a respective one of the driving transistors and a first power line for storing voltage corresponding to the data signal.

According to a further aspect of the invention, the plurality of driving transistors includes a semiconductor layer of poly silicon.

According to a still further aspect of the invention, the plurality of driving transistors includes a semiconductor layer to be recrystallized by a laser.

Other features of the present invention are achieved by providing a method of fabricating a light emitting display which includes a plurality of light emitting devices formed so as to be adjacent to a region where data and scan lines cross each other, and a plurality of pixel circuits, each having a driving transistor for supplying current corresponding to a data signal of the data line to a respective one of the light emitting devices, the method comprising the steps of: forming the pixel circuits; and forming the light emitting devices so as to be electrically connected to the pixel circuits. The driving transistors are formed by a method comprising the steps of: forming semiconductor layers for the driving transistors on a substrate so as to be positioned differently with respect to each other in a horizontal direction; crystallizing the semiconductor layers; forming a first insulating layer to cover the semiconductor layers; and forming a gate electrode of each driving transistor on the first insulating layer.

According to an aspect of the invention, the forming of the driving transistors further comprises: forming a second insulating layer to cover the gate electrodes; and forming source and drain electrodes on the second insulating layer so as to be electrically connected to source and drain regions, respectively, of the semiconductor layer.

According to another aspect of the invention, the driving transistors connected to odd numbered data lines are aligned on a first horizontal line, and the driving transistors connected to even numbered data lines are aligned on a second horizontal line between the first horizontal line and one of the scan lines.

According to another aspect of the invention, the driving transistors are disposed in zigzag fashion on the first and second horizontal lines.

According to another aspect of the invention, the forming of each pixel circuit comprises: forming a switching transistor so as to be connected to a scan line and a data line so as to supply a data signal from the data line to a gate electrode of a driving transistor; and forming a storage capacitor connected between the gate electrode of the driving transistor and a first power line for storing voltage corresponding to the data signal.

According to a further aspect of the invention, the semiconductor layer includes poly silicon.

Still other aspects of the present invention are achieved by providing a method of fabricating a light emitting display which includes a plurality of light emitting devices formed so as to be adjacent to a region where data and scan lines cross each other, and a plurality of pixel circuits, each having a driving transistor supplying, to a respective one of the light emitting devices, current corresponding to a data signal of the data line, the method comprising the steps of: forming the pixel circuits; and forming the light emitting devices so as to be electrically connected to respective ones of the pixel circuits. The driving transistors are formed by a method comprising the steps of: forming semiconductor layers for the driving transistors on a substrate so as to be positioned differently with respect to each other in a vertical direction; crystallizing the semiconductor layers; forming a first insulating layer to cover the semiconductor layers; and forming gate electrodes of the driving transistors on the first insulating layer.

According to an aspect of the invention, the forming of the driving transistors further comprises: forming a second insulating layer to cover the gate electrodes; and forming source and drain electrodes on the second insulating layer so as to be electrically connected to source and drain regions, respectively, of the semiconductor layer.

According to another aspect of the invention, the driving transistors connected to odd numbered scan lines are aligned on a first vertical line, and the driving transistors connected to even numbered scan lines are aligned on a second horizontal line between the first horizontal line and one of the data lines.

According to another aspect of the invention, the driving transistors are disposed in zigzag fashion on the first and second vertical lines.

According to a further aspect of the invention, the forming of each pixel circuit comprises: forming a switching transistor so as to be connected to a scan line and a data line, and so as to supply a data signal from the data line to a gate electrode of a respective driving transistor; and forming a storage capacitor connected between the gate electrode of the respective driving transistor and a first power line for storing voltage corresponding to the data signal.

According to a still further aspect of the invention, the semiconductor layer includes poly silicon.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a circuit diagram of a light emitting display;

FIG. 2 is a plan view of the light emitting display of FIG. 1;

FIG. 3 illustrates a method of crystallizing a semiconductor layer of a transistor in the light emitting display of FIGS. 1 and 2;

FIG. 4 illustrates a stripe pattern which appears on the light emitting display of FIGS. 1 and 2;

FIG. 5 is a circuit diagram of a light emitting display according to a first embodiment of the present invention;

FIG. 6 is a plan view of the light emitting display according to the first embodiment of the present invention;

FIG. 7 is a partial section view of FIG. 6, taken along line VII-VII′;

FIG. 8 is a partial section view of FIG. 6, taken along line VIII-VIII′;

FIG. 9 is a circuit diagram of a light emitting display according to a second embodiment of the present invention; and

FIG. 10 is a plan view of the light emitting display according to the second embodiment of the present invention.

### DETAILED DESCRIPTION OF THE INVENTION

Hereinafter, preferable embodiments according to the present invention will be described with reference to the accompanying drawings, wherein the preferred embodiments of the present invention are provided to be readily understood by those skilled in the art.

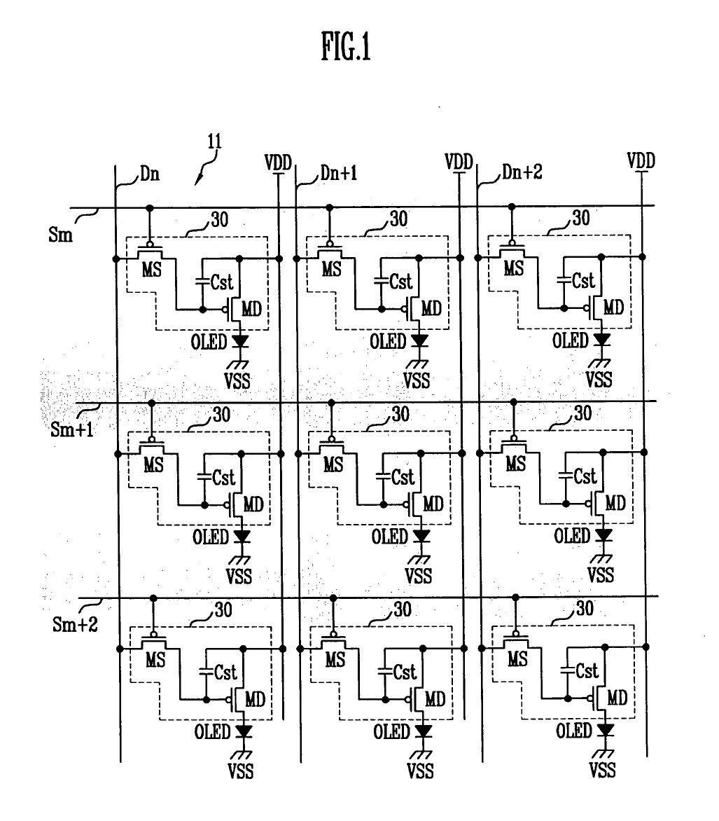

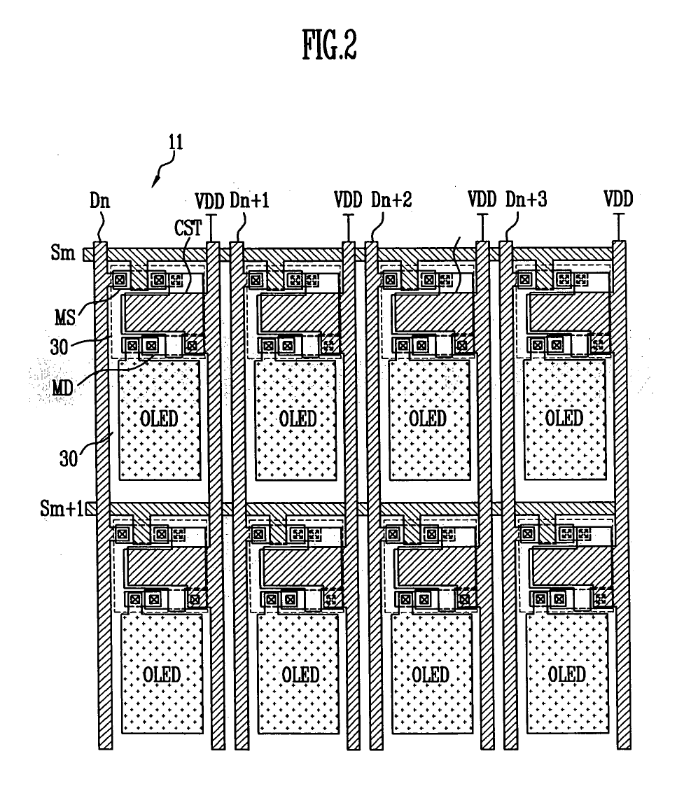

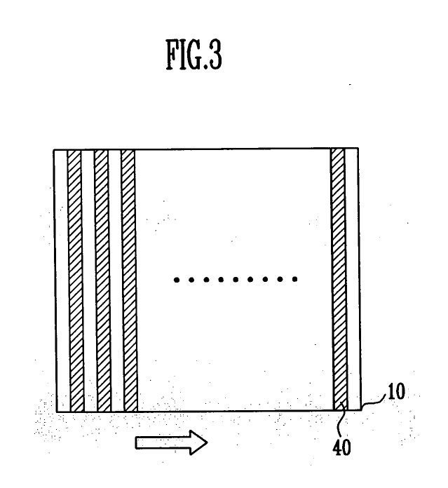

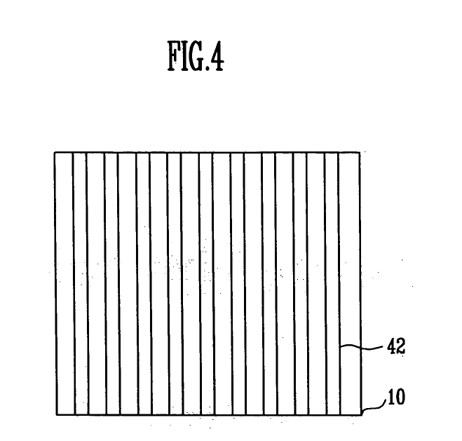

FIG. 1 is a circuit diagram of a light emitting display; FIG. 2 is a plan view of the light emitting display of FIG. 1; FIG. 3 illustrates a method of crystallizing a semiconductor layer of a transistor in the light emitting display of FIGS. 1 and 2; and FIG. 4 illustrates a stripe pattern which appears on the light emitting display of FIGS. 1 and 2.

Referring to FIGS. 1 and 2, a light emitting display generally comprises a plurality of pixels 11 including a plurality of scan lines S, a plurality of data lines D, and a first power line VDD.

Each pixel 11 comprises an organic light emitting device OLED and a pixel circuit 30 controlling the organic light emitting device OLED to emit light. The scan line S is horizontally formed, and the data line D and the first power line VDD are vertically formed. The pixel 11 receives a data signal from the data line D when a selection signal is applied to the scan line S, and emits light corresponding to the data signal.

The organic light emitting device OLED has an anode electrode connected to the pixel circuit 30 and a cathode electrode connected to a second power line VSS.

The organic light emitting device OLED further comprises an emitting layer, an electron transport layer, and a hole transport layer, which are interposed between the anode electrode and the cathode electrode. Additionally, the light emitting display comprise an electron injection layer and a hole injection layer. In this light emitting display, when voltage is applied between the anode electrode and the cathode electrode, electrons generated by the cathode electrode are moved to the emitting layer via the electron injection layer and the electron transport layer, and holes generated by the anode electrode are moved to the emitting layer via the hole injection layer and the hole transport layer. Then, the electrons from the electron transport layer and the holes from the hole transport layer are recombined in the emitting layer, thereby emitting light.

Each pixel circuit 30 comprises: a driving thin film transistor (TFT) MD connected between the first power line VDD and the organic light emitting device OLED; a switching TFT MS connected to the driving TFT MD, the data line D and the scan line S; and a storage capacitor Cst connected between the gate and source electrodes of the driving TFT MD. Each of the driving TFT MD and the switching TFT MS preferably comprises a P-type metal oxide semiconductor field effect transistor (MOSFET).

The switching TFT MS comprises a gate electrode connected to the scan line S, a source electrode connected to the data line D, and a drain electrode connected to a first terminal of the storage capacitor Cst. The switching TFT MS is turned on in response to the selection signal on the scan line S, and supplies the data signal from the data line D to the storage capacitor Cst. At this point, the storage capacitor Cst stores voltage corresponding to the data signal.

The driving TFT MD comprises a gate electrode connected to the first terminal of the storage capacitor Cst, a source electrode connected to a second terminal of the storage capacitor Cst and the first power line VDD, and a drain electrode connected to the anode electrode of the organic light emitting device OLED. The driving TFT MD controls the intensity of current flowing from the first power line VDD to the organic light emitting device OLED in correspondence to the data signal supplied through the switching TFT MS. At this point, the driving TFTs MD of the pixels 11 are aligned in the vertical and horizontal directions, respectively.

In each pixel 11 of the light emitting display, the switch TFT MS is turned on in response to the selection signal on the scan line S, and supplies the data signal from the data line D to the gate electrode of the driving TFT MD. At this point, the storage capacitor Cst stores a voltage difference between the driving voltage supplied through the first power line VDD and the data signal supplied to the gate electrode of the driving TFT MD. Furthermore, the driving TFT MD controls the intensity of the current flowing from the first power line VDD to the organic light emitting device OLED in response to the data signal supplied to its gate electrode, thereby adjusting the brightness of the organic light emitting device OLED. In addition, when the switching TFT MS is turned off, the driving TFT MD constantly supplies current to the organic light emitting device OLED using the voltage stored in the storage capacitor Cst until the data signal of a subsequent frame is supplied, thereby keeping the brightness of the organic light emitting device OLED constant.

In each pixel 11 of the light emitting display, the driving TFT MD of the pixel circuit 30 is employed to control the intensity of the current supplied to the organic light emitting device OLED in correspondence to the voltage applied to its gate electrode, thereby adjusting the brightness of the organic light emitting device OLED. At this point, the current Ids supplied to the organic light emitting device OLED through the driving TFT MD is determined on the basis of the following equation:

$$Ids = \frac{1}{2} X \frac{W}{L} X μ {Cox ( Vgs - Vth )}^{2} \qquad Equation 1$$

where W and L are the width and the length of the driving TFT MD, respectively; Vgs is a voltage applied between the gate and source electrodes of the driving TFT MD; Vth is a threshold voltage of the driving TFT MD; μ is mobility; and Cox is the gate capacity of the driving TFT MD per unit area.

Referring to Equation 1, the current Ids supplied through the driving TFT MD depends on the data voltage supplied to the gate electrode of the driving TFT (MD), the threshold voltage (Vth), and the mobility (i). However, there is a problem in that the characteristics (e.g., threshold voltage, mobility, etc.) of the respective driving TFTs MD are not uniform due to a laser crystallization process which crystalizes amorphous silicon into poly silicon.

In the process of fabricating the light emitting display, a process of forming a semiconductor layer of the TFTs MD and MS of the each pixel 11 includes the laser crystallization process which crystalizes an amorphous silicon layer into a poly silicon layer. For example, as shown in FIG. 3, an amorphous silicon layer patterned on a substrate 10 is scanned in the horizontal direction by a line beam 40 of an excimer laser in the laser crystallization process, and thus the amorphous silicon layer is crystallized into poly silicon. In this regard, the amorphous silicon layer is repeatedly alternated between melting and solidifying by a laser beam having a short frequency and high energy so that it is recrystallized into the poly silicon layer.

Such a laser crystallization process has an advantage in that it is possible to form a poly silicon layer on a large sized substrate, but it has a problem in that energy deviation in the laser beam during laser scanning operations causes variation in such characteristics as the size of a crystal grain, the mobility, etc. of the poly silicon layer. Therefore, the characteristics of the poly silicon layer are not uniform along a scanning direction, i.e., the horizontal direction. When this poly silicon layer is used as the semiconductor layer of a driving TFT MD, the threshold voltage, the mobility, etc. of the driving TFTs MD are not uniform in the vertical direction, so that brightness deviation appears vertically in the light emitting display. Therefore, in the light emitting display, as shown in FIG. 4, a stripe pattern 42 due to the non-uniform characteristics of the driving TFT MD is vertically formed along the scan direction of the laser. Such a vertical stripe pattern 42 is easily seen by a user, thereby deteriorating picture quality and decreasing the yield of the light emitting display.

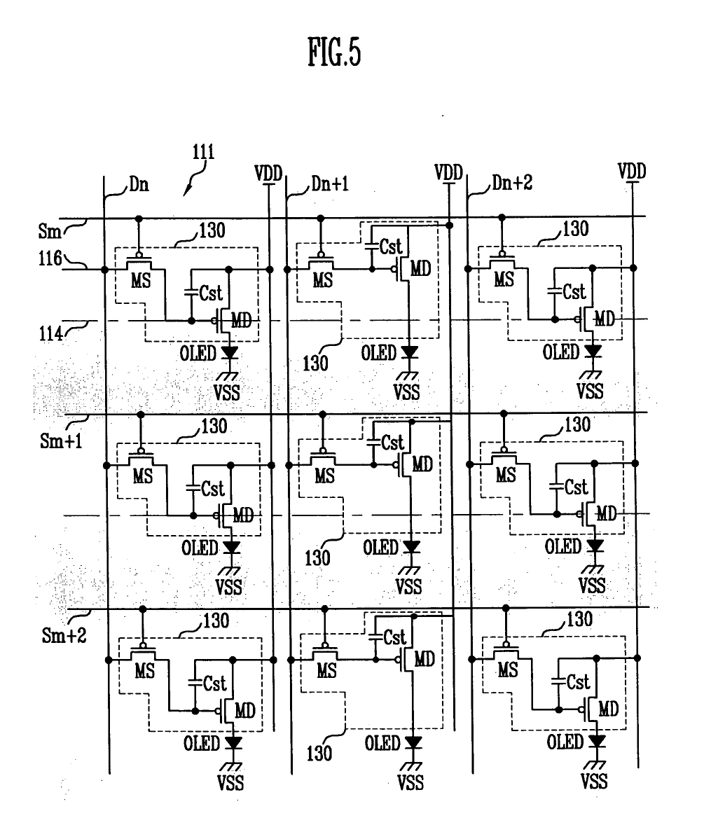

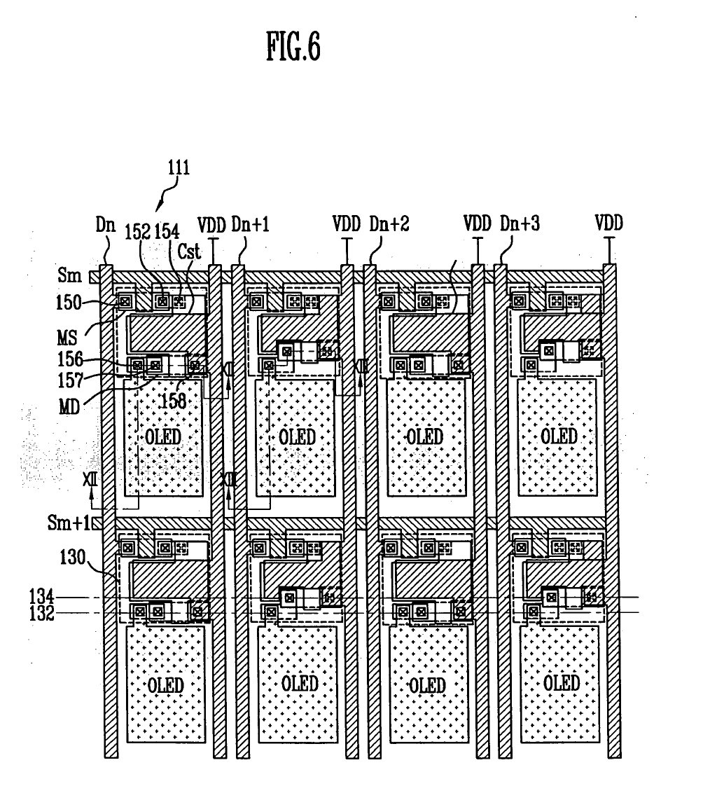

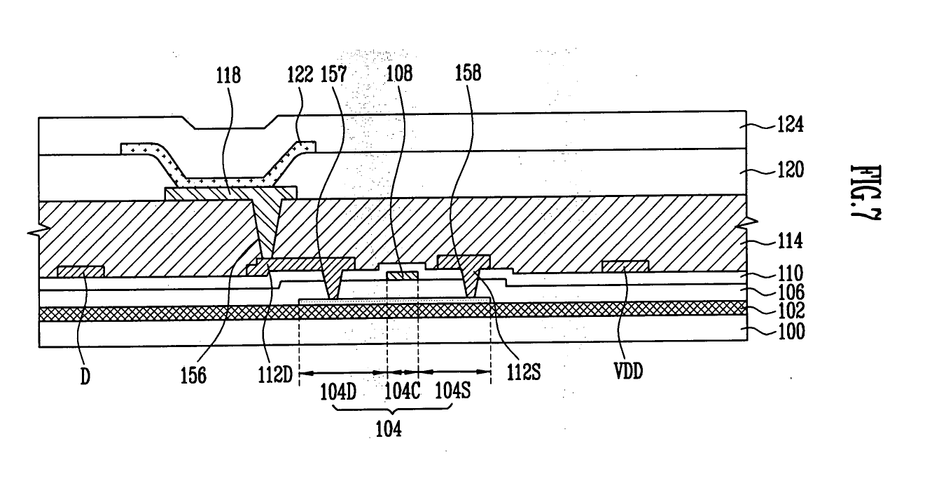

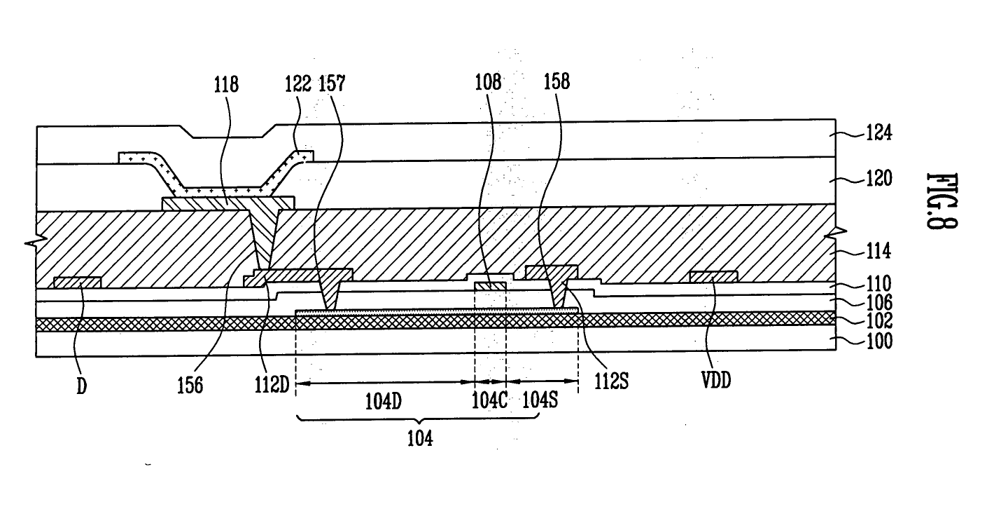

FIG. 5 is a circuit diagram of a light emitting display according to a first embodiment of the present invention; FIG. 6 is a plan view of the light emitting display according to the first embodiment of the present invention; FIG. 7 is a partial section view of FIG. 6, taken along line VII-VII′; and FIG. 8 is a partial section view of FIG. 6, taken along line VIII-VIII′.

Referring to FIGS. 5 and 6, a light emitting display according to a first embodiment of the present invention comprises a plurality of pixels 111 placed adjacent to regions where data lines D and scan lines S cross each other. Each pixel 111 comprises a pixel circuit 130 including an organic light emitting device OLED, and a driving thin film transistor (TFT) MD for supplying, to the organic light emitting device OLED, current corresponding to a data signal of the data line D. Furthermore, the positions of the driving TFTs MD are alternately varied in the a horizontal direction.

In each pixel 111, the pixel circuit 130 controls the organic light emitting device OLED to emit light. The scan line S is formed horizontally, and the data line D and a first power line VDD are formed vertically. Each pixel 111 receives a data signal from the data line D when a selection signal is applied to the scan line S, and emits light corresponding to the received data signal.

Each pixel 111 comprises: the driving TFT MD connected between the first power line VDD and the organic light emitting device OLED; a switching TFT MS connected to the driving TFT MD, the data line D, and the scan line S; and a storage capacitor Cst connected between gate and source electrodes of the driving TFT MD. The driving TFT MD and the switching transistor MS are each preferably formed of a P-type metal oxide semiconductor field effect transistor (MOSFET).

The switching TFT MS comprises a gate electrode connected to the scan line, a source electrode connected to the data line D via a first contact hole 150, and a drain electrode connected to a first terminal of the storage capacitor Cst via second and third contact holes 152 and 154. In this regard, the switching TFT MS is turned on in response to a selection signal of the scan line S, and supplies the data signal from the data line D to the storage capacitor Cst. At this point, the storage capacitor Cst stores a voltage corresponding to the data signal. Furthermore, the switching TFT MS of each pixel circuit 130 is placed adjacent to the scan line S which is formed horizontally.

The driving TFT MD comprises the gate electrode connected to the first terminal of the storage capacitor Cst, the source electrode connected to a second terminal of the storage capacitor Cst and the first power line VDD via a fourth contact hole 158, and a drain electrode connected to an anode electrode of the organic light emitting device OLED via fifth and sixth contact holes 157 and 156. The driving TFT MD controls the intensity of current flowing from the first power line VDD to the organic light emitting device OLED in correspondence to the us data signal supplied through the switching TFT MS.

In each pixel 111 of the light emitting display, according to the first embodiment of the present invention, the switch TFT MS is turned on when the selection signal is transmitted to the scan line S, and supplies the data signal from the data line D to the gate electrode of the driving TFT MD. At this point, the storage capacitor Cst stores a voltage difference between the driving voltage supplied through the first power line VDD and the data signal supplied to the gate electrode of the driving TFT MD. Furthermore, the driving TFT MD controls the intensity of the current flowing from the first power line VDD to the organic light emitting device OLED in response to the data signal supplied to its gate electrode, thereby adjusting the brightness of the organic light emitting device OLED. In addition, when the switching TFT MS is turned off, the driving TFT MD supplies current constantly to the organic light emitting device OLED using the voltage stored in the storage capacitor Cst until the data signal of a subsequent frame is supplied, thereby keeping the brightness of the organic light emitting device OLED constant.

Meanwhile, the driving TFTs MD formed in the respective pixels 111 are alternately varied in position with respect to the horizontal direction. That is, the driving TFTs MD of the respective pixel circuits 130 connected to odd numbered data lines D1, D3, . . . , D2n−1 are aligned on a first horizontal line 132, where n is a natural number. The driving TFTs MD of the respective pixel circuits 130 connected to even numbered data lines D2, D4, . . . , D2n are aligned on a second horizontal line 134 disposed between the first horizontal line 132 and the scan line S, where n is a natural number. Consequently, the driving TFTs MD of the adjacent pixel circuit 130 are formed on the first and second horizontal lines 132 and 134, respectively. Thus, the driving TFTs MD are formed in zigzag fashion with respect to the horizontal direction.

In more detail, the driving TFTs MD aligned on the first horizontal line 132 are fabricated as follows. Referring to FIG. 7, a buffer layer 102 is formed on a substrate 100. Then, a semiconductor layer 104 is formed on the buffer layer 102 so as to have a predetermined pattern corresponding to the first horizontal line 132.

The semiconductor layer 104 formed on the first horizontal line 132 is made of poly silicon crystallized from amorphous silicon. The amorphous silicon is crystallized into the poly silicon by applying thereto, in a horizontal direction, a line beam of a laser crystallization process using an excimer laser.

After the semiconductor layer 104 is formed, a gate insulating layer 106 is formed on the buffer layer 102 and the semiconductor layer 104. The gate insulating layer 106 includes an insulating material such as SiO₂ or the like. Then, a gate electrode 108 is formed on the gate 8 insulating layer 106, overlying the semiconductor layer 104. The gate electrode 108 includes a conductive material such as Al, MoW, Al/Cu, or the like, and the scan line S is made of the same material as the gate electrode 108.

Then, the substrate 100 is doped with an ion, thereby doping a source region 104S and a drain region 104D of the semiconductor layer 104 with the ion. Thus, a channel 104C is formed between the source region 104S and drain region 104D of the semiconductor layer 104.

After forming the gate electrode 108, an insulating material 110 is formed on the gate electrode 108. Then, the insulating material 110 and the gate insulating layer 106 are penetrated with fourth contact hole 158 and fifth contact hole 157 so as to expose the semiconductor layer 104 therethrough.

After the fourth and fifth contact holes 158 and 157, respectively, are formed, a source electrode 112S and a drain electrode 112D are formed on the interlaying insulating layer 110, the source electrode 112S having a predetermined pattern and including a metal material. The source electrode 112S and the drain electrode 112D are electrically connected to the source region 104S and the drain region 104D, respectively, of the semiconductor layer 104 via the fourth and fifth contact holes 158 and 157, respectively. Furthermore, the metal materials of the source electrode 112S and the drain electrode 112D are used as the data line D and the first power line VDD according to their positions.

After forming the metal material on the insulating material 110, a passivation layer 114 is formed on the metal material. Then, a sixth contact hole 156 is formed in the passivation layer 114 so as to expose the drain electrode 112D therethrough. After formation of the sixth contact hole 156, a lower electrode layer 118 is formed on the passivation layer 114, and is used as the anode electrode of the organic light emitting device OLED. The lower electrode layer 118 is electrically connected to the drain electrode 112D through the sixth contact hole 156. Then, a pixel definition layer 120 is formed on the lower electrode layer 118 and the passivation layer 114.

The pixel definition layer 120 is provided with an opening so as to define a pixel region, and an organic layer 122 is formed in the opening. Then, an upper electrode layer 124 is formed on the organic layer 122 and the pixel definition layer 120, and is used as a cathode electrode of the organic light emitting device OLED.

On the other hand, the driving TFTs MD aligned with the second horizontal line 134 of FIG. 6 are fabricated as follows. Referring to FIG. 8, the buffer layer 102 is formed on the substrate 100. Then, the semiconductor layer 104 is formed on the buffer layer 102, the semiconductor layer 104 having a predetermined pattern corresponding to the second horizontal line 134.

The semiconductor layer 104 formed on the second horizontal line 134 is made of poly silicon crystallized from amorphous silicon. The amorphous silicon is crystallized into poly silicon by applying thereto, and in the horizontal direction, the line beam of a laser crystallization process using an excimer laser.

After the semiconductor layer 104 is formed, the gate insulating layer 106 is formed on the buffer layer 102 and the semiconductor layer 104. The gate insulating layer 106 includes an insulating material such as SiO₂ or the like. Then, the gate electrode 108 is formed on the gate insulating layer 106, overlying the semiconductor layer 104. The gate electrode 108 includes a conductive material such as Al, MoW, Al/Cu, or the like, and the scan line S is made of the same material as the gate electrode 108.

Then, the substrate 100 is doped with an ion, thereby doping the source region 104S and the drain region 104D of the semiconductor layer 104 with the ion. Thus, the channel 104C is formed between the source region 104S and drain region 104D of the semiconductor layer 104.

After forming the gate electrode 108, the insulating material 110 is formed on the gate electrode 108. Then, the insulating material 110 and the gate insulating layer 106 are penetrated with fourth and fifth contact holes 158 and 157, respectively, so as to expose the semiconductor layer 104 therethrough.

After the fourth and fifth contact holes 158 and 157, respectively, are formed, the source electrode 112S and the drain electrode 112D are formed on the insulating layer 110, the source electrode 112S having a predetermined pattern and including metal material. The source electrode 112S and the drain electrode 112D are electrically connected to the source region 104S and the drain region 104D, respectively, of the semiconductor layer 104 via the fourth and fifth contact holes 158 and 157, respectively. Furthermore, the metal materials of the source electrode 112S and the drain electrode 112D are used as the data line D and the first power line VDD according to their positions.

After forming the metal material on the insulating material 110, the passivation layer 114 is formed on the metal material 112. Then, the sixth contact hole 156 is formed in the passivation layer 114 so as to expose the drain electrode 112D therethrough. After formation of the sixth contact hole 156, the lower electrode layer 118 is formed on the passivation layer 114 and used as the anode electrode of the organic light emitting device OLED. The lower electrode layer 118 is electrically connected to the drain electrode 112D through the sixth contact hole 156. Then, the pixel definition layer 120 is formed on the lower electrode layer 118 and the passivation layer 114.

The pixel definition layer 120 is provided with an opening so as to define the pixel region, and the organic layer 122 is formed in the opening. Then, the upper electrode layer 124 is formed on the organic layer 122 and the pixel definition layer 120, and is used as the cathode electrode of the organic light emitting device OLED.

As described above, in the light emitting display according to the first embodiment of the present invention, the driving TFTs MD formed in the respective pixel circuits 130 are disposed in zigzag fashion with respect to the horizontal direction, thereby compensating for the non-uniform characteristics, such as the threshold voltage, the mobility, etc. of the driving TFTs MD due to the laser crystallization process wherein amorphous silicon is crystalized into poly silicon. Therefore, the picture quality of the light emitting display is enhanced.

In more detail, in the light emitting display according to the first embodiment of the present invention, the excimer laser is applied differently to the respective semiconductor layers 104 of the adjacent driving TFTs MD with respect to the horizontal direction, leaving a time lag. Furthermore, the excimer laser is applied differently to the respective semiconductor layers 104 of the adjacent driving TFTs MD with respect to the vertical direction, leaving a time lag. That is, with regard to the horizontal direction, the line beam of the excimer laser is first applied to the semiconductor layer 104 of the driving TFT MD aligned with the second horizontal line 134, and is then applied to the semiconductor layer 104 of the driving TFT MD aligned with the first horizontal line 132.

Thus, the characteristics of each semiconductor layer 104 of the driving TFTs MD aligned with the first horizontal line 132 and second horizontal line 134 are not rendered uniform along the scanning direction of the excimer laser and along the direction perpendicular to the scanning direction, respectively. Therefore, the stripe pattern appears randomly in a direction perpendicular to the scanning direction of the excimer laser because of the non-uniform characteristics of the adjacent driving TFTs MD with respect to the horizontal and vertical directions. Thus, in the light emitting display according to the first embodiment of the present invention, the driving TFTs MD are disposed in zigzag fashion with respect to the scanning direction of the excimer laser, thereby preventing the stripe pattern from appearing perpendicular to the scanning direction of the excimer laser, enhancing the picture quality, and increasing the yield of the light emitting display.

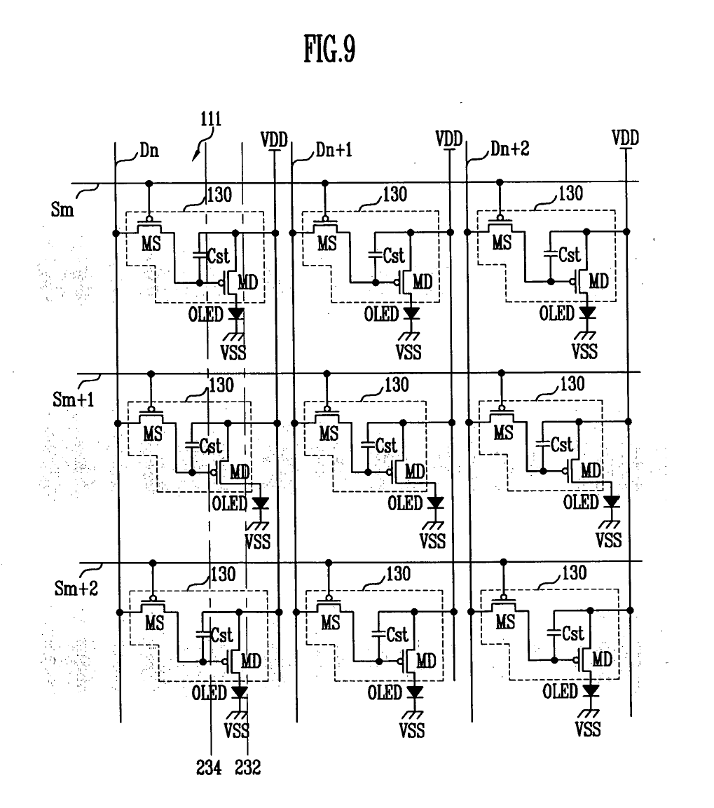

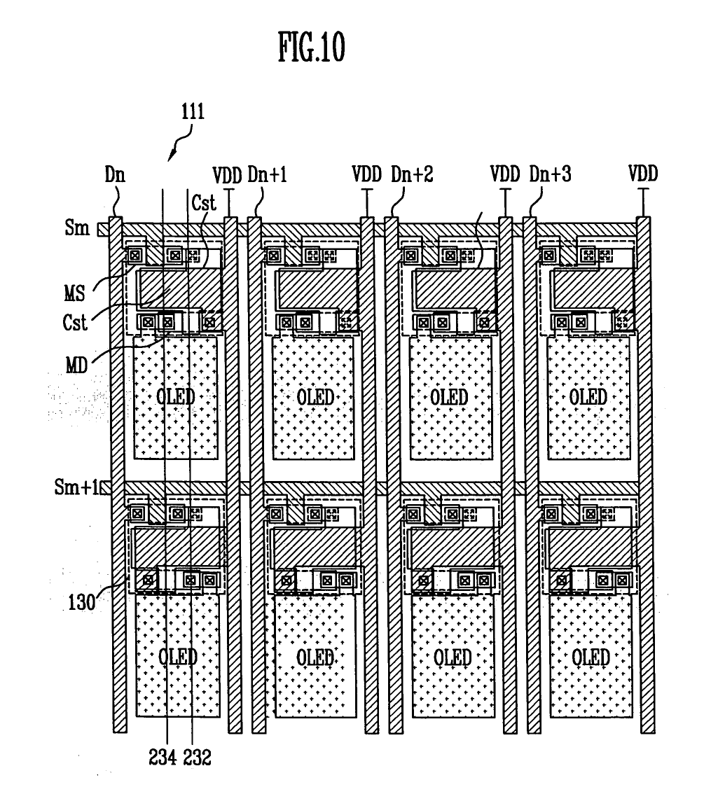

FIG. 9 is a circuit diagram of a light emitting display according to a second embodiment of the present invention; and FIG. 10 is a plan view of the light emitting display according to the second embodiment of the present invention.

Referring to FIGS. 9 and 10, a light emitting display according a second embodiment of the present invention has the same configuration as that of the first embodiment, except that the driving TFTs MD of respective pixel circuits 130 are disposed in zigzag fashion with respect to a vertical direction. Thus, repetitive description is avoided below as appropriate.

The driving TFTs MD of the respective pixel circuits 130 connected to odd numbered scan lines S1, S3, . . . , S2m−1 are aligned in a first vertical line 232, where m is a natural number. The driving TFTs MD of the respective pixel circuits 130 connected to even numbered scan lines S2, S4, . . . , S2n are aligned in a second vertical line 234 disposed between the first vertical line 232 and the data line D, where n is a natural number. Consequently, the driving TFTs MD are formed on the first and second vertical lines 132 and 134, respectively. Thus, the driving TFTs MD are formed in zigzag fashion with respect to the vertical direction.

As described above, in the light emitting display according to the second embodiment of the present invention, the driving TFTs MD formed in the respective pixel circuits 130 are disposed in zigzag fashion with respect to the vertical direction, thereby compensating for the non-uniform characteristics, such as the threshold voltage, the mobility, etc., of the driving TFTs MD due to the laser crystallization process wherein amorphous silicon is crystallized into poly silicon. Therefore, the picture quality of the light emitting display is enhanced.

In more detail, in the light emitting display according to the second embodiment of the present invention, the excimer laser is applied differently to the respective semiconductor layers 104 of the adjacent driving TFTs MD with respect to the vertical direction, leaving a time lag. Furthermore, the excimer laser is applied differently to the respective semiconductor layers 104 of the adjacent driving TFTs MD with respect to the vertical direction, leaving a time lag. That is, with regard to the horizontal direction, the line beam of the excimer laser is first applied to the semiconductor layer 104 of the driving TFT MD aligned on the second vertical line 234, and is then applied to the semiconductor layer 104 of the driving TFT MD aligned on the first vertical line 232.

Thus, the characteristics of each semiconductor layer 104 of the driving TFTs MD aligned on the first and second vertical lines 232 and 234, respectively, are not rendered uniform along the scanning direction of the excimer laser and along a direction perpendicular to the scanning direction, respectively. Therefore, the stripe pattern appears randomly in the direction perpendicular to the scanning direction of the excimer laser because of the non-uniform characteristics of the adjacent driving TFTs MD with respect to the horizontal and vertical directions. Thus, in the light emitting display according to the second embodiment of the present invention, the driving TFTs MD are disposed in zigzag fashion with respect to the scanning direction of the excimer laser, thereby preventing the stripe pattern from appearing perpendicular to the scanning direction of the excimer laser, enhancing the picture quality, and increasing the yield of the light emitting display.

As described above, the present invention provides a light emitting display and a fabrication method thereof, in which driving TFTs of pixel circuits are disposed in zigzag fashion with respect to a horizontal direction or a vertical direction, thereby preventing a stripe pattern from appearing perpendicular to a scanning direction of a line beam emitted from an excimer laser.

Although a few embodiments of the present invention have been shown and described, it will be appreciated by those skilled in the art that changes can be made in this embodiment without departing from the principles and spirit of the invention, the scope of which is defined in the claims and their equivalents.

1. A light emitting display, comprising
a plurality of light emitting devices formed so as to be adjacent to a region wherein data lines and scan lines cross each other; and
a plurality of pixel circuits, each including a driving transistor for supplying, to a respective one of the light emitting devices, current corresponding to a data signal on a respective one of the data lines;
wherein positions of the driving transistors are different from each other with respect to at least one of a horizontal direction and a vertical direction.

2. The light emitting display according to claim 1, wherein driving transistors connected to odd numbered data lines are aligned on a first horizontal line; and
wherein driving transistors connected to even numbered data lines are aligned on a second horizontal line located between the first horizontal line and said respective one of the scan lines.

3. The light emitting display according to claim 2, wherein the driving transistors are disposed in zigzag fashion on the first and second horizontal lines.

4. The light emitting display according to claim 1, wherein driving transistors connected to odd numbered scan lines are aligned on a first vertical line; and
wherein driving transistors connected to even numbered scan lines are aligned on a second vertical line located between the first vertical line and said respective one of the data lines.

5. The light emitting display according to claim 4, wherein the driving transistors are disposed in zigzag fashion on the first and second vertical lines.

6. The light emitting display according to claim 1, wherein each pixel circuit further comprises:
a switching transistors for supplying a data signal from said respective one of the data lines to a gate electrode of a respective one of the driving transistors in response to a selection signal of a scan signal; and
a storage capacitor connected between the gate electrode said respective one of the driving transistors and a first power line for storing a voltage corresponding to the data signal.

7. The light emitting display according to claim 1, wherein each of the driving transistors includes a semiconductor layer of poly silicon.

8. The light emitting display according to claim 1, wherein each of the driving transistors includes a semiconductor layer to be recrystallized by a laser.

9. A method of fabricating a light emitting display which includes a plurality of light emitting devices formed adjacent to a region where data lines and scan lines cross each other, and a plurality of pixel circuits, each having a driving transistors for supplying current corresponding to a data signal of a respective one of the data lines to a respective one of the light emitting devices, the method comprising the steps of:
forming the pixel circuits including the driving transistors; and
forming the light emitting devices so as to be electrically connected to respective ones of the pixel circuits;
wherein the driving transistors are formed by a method comprising the steps of:
forming semiconductor layers for the driving transisors on a substrate so that the driving transistors are positioned differently from each other with respect to a horizontal direction;
crystallizing the semiconductor layers;
forming a first insulating layer so as to cover the semiconductor layers; and
forming gate electrodes of the driving transistors on the first insulating layer.

10. The method according to claim 9, wherein the method by means of which the driving transistors are formed further comprises the steps of:
forming a second insulating layer so as to cover the gate electrodes; and
forming source electrodes and drain electrodes on the second insulating layer so that the source electrodes and the drain electrodes are electrically connected to source regions and drain regions, respectively, of the semiconductor layer.

11. The method according to claim 9, wherein driving transistors connected to odd numbered data lines are aligned on a first horizontal line; and
wherein driving transistors connected to even numbered data lines are aligned on a second horizontal line located between the first horizontal line and one of the scan lines.

12. The method according to claim 11, wherein the driving transistors are disposed in zigzag fashion on the first and second horizontal lines.

13. The method according to claim 9, wherein the step of forming the pixel circuits comprises:
forming switching transistors, each connected to a respective one of the scan lines and a respective one of the data lines for supplying a data signal from said respective one of the data lines to a gate electrode of a respective one of the driving transistors; and
forming storage capacitors, each connected between the gate electrode of a respective one of the driving transistors and a first power line for storing a voltage corresponding to the data signal.

14. The method according to claim 9, wherein the semiconductor layer comprises poly silicon.

15. A method of fabricating a light emitting display which includes a plurality of light emitting devices formed adjacent to a region where data lines and scan lines cross each other, and a plurality of pixel circuits, each having a driving transistor for supplying current corresponding to data signal of a respective one of the data lines to a respective one of the light emitting devices, the method comprising the steps of:
forming the pixel circuits including the driving transistors; and
forming the light emitting devices so as to be electrically connected to respective ones of the pixel circuits;
wherein the driving transistors are formed by a method comprising the steps of:
forming semiconductor layers for the driving transisors on a substrate so that the driving transistors are positioned differently from each other with respect to a vertical direction;
crystallizing the semiconductor layers;
forming a first insulating layer so as to cover the semiconductor layers; and
forming gate electrodes of the driving transistors on the first insulating layer.

16. The method according to claim 15, wherein the method by means of which the driving transistors are formed further comprises the steps of:
forming a second insulating layer so as to cover the gate electrodes; and
forming source electrodes and drain electrodes on the second insulating layer so that the source electrodes and the drain electrodes are electrically connected to source regions and drain regions, respectively, of the semiconductor layer.

17. The method according to claim 15, wherein driving transistors connected to odd numbered scan lines are aligned on a first vertical line; and
wherein driving transistors connected to even numbered scan lines are aligned on a second horizontal line located between the first horizontal line and one of the data lines.

18. The method according to claim 17, wherein the driving transistors are disposed in zigzag fashion on the first and second vertical lines.

19. The method according to claim 15, wherein the step of forming the pixel circuits comprises:
forming switching transistors, each connected to a respective one of the scan lines and a respective one of the data lines for supplying a data signal from said respective one of the data lines to a gate electrode of a respective one of the driving transistors; and
forming storage capacitors, each connected between the gate electrode of a respective one of the driving transistors and a first power line for storing a voltage corresponding to said one of the data signals.

20. The method according to claim 15, wherein the semiconductor layer comprises poly silicon.
